(19) United States
(12) Patent Application Publication
(10) Pub. No.: US 2024/0356273 A1
(43) Pub. Date: Oct. 24, 2024

(54) Connection element and system having a connection element

(71) Applicant: SICK Engineering GmbH, Ottendorf-Okrilla (DE)

(72) Inventors: Robert JEHN, Waldkirch (DE); David WALDE, Waldkirch (DE)

(21) Appl. No.: 18/637,625

(22) Filed: Apr. 17, 2024

(30) Foreign Application Priority Data
Apr. 21, 2023 (DE) 102023110257.5

(51) Int. Cl. H01R 13/527; H01B 17/30; H01R 12/72

(52) U.S. Cl. CPC H01R 13/527; H01B 17/306; H01R 12/721

(57) ABSTRACT

A system has a connection element for the electrical connection of a first electrical assembly and a second electrical assembly. One of the assemblies is disposed in an explosion protected space and the connection element is arranged in an opening to the explosion protected space and closes the opening. The connection element has a cylindrical sleeve releasably arrangeable in a holder of the opening. The connection element has at least one printed circuit board in the cylindrical sleeve, with the printed circuit board having a plurality of conductor tracks for the electrical connection of the first electrical assembly and the second electrical assembly, with the connection element having a cast part. The printed circuit board is fixed and sealed in the cylindrical sleeve by means of the cast part, and with respective ends of the printed circuit board having the respective conductor tracks projecting from the cast part.

The present invention relates to a connection element for the electrical connection of a first electrical assembly and a second electrical assembly and to a system having a connection element.

Explosion prevention and protection is a branch of engineering that deals with the prevention of and protection from explosions and their effects. It is part of the field of safety engineering and serves for the prevention of injuries to persons or damage to objects. They can be caused by human error (misjudgment of existing work conditions) or defective work equipment that represents effective ignition sources of the system to be evaluated. Explosion prevention and protection is achieved by implementing integrated explosion safety by primary, secondary, and tertiary protection goals. They first comprise avoidance strategies that have to avoid the development of explosive mixtures by substitution, for example. Only if this cannot be implemented do secondary technical measures and also, where applicable, organizational measures take effect that have the general protection goal of at all costs avoiding the ignition of explosive mixtures that occur. Only if this cannot be safely prevented technologically does the tertiary protection goal take effect of limitation of impact in explosion prevention and protection (e.g. flameproof construction, outdoor installation with protection distances and optionally also safety distances).

The basis for this is formed by statutory regulations such as EU hazardous substances law, the use of work equipment directive or the ATEX directives of the European Union.

The type of ignition protection is a designation from explosion prevention and protection that stands for different construction principles in this field. The basic idea behind every type of ignition protection is to minimize the risk of a simultaneous presence of an explosive atmosphere and ignition sources and/or to prevent the propagation of an explosion. For example, an explosion may occur in an Ex d flameproof enclosure, but flame propagation to external is prevented.

Explosions occur when an explosive atmosphere is ignited by an ignition source. To prevent the explosion, care must be taken that all the required components do not occur simultaneously. Whereas the presence of the explosive atmosphere is to be prevented in primary explosion prevention and protection, the aim of secondary explosion prevention and protection is the avoidance of ignition sources. Different types of ignition protection that are described in different international and European standards have been defined for the different types for which the ignition sources can be prevented. They are likewise made use of within the directives of the European Community.

For example, types of ignition protection are distinguished for the different applications for a gas and dust atmosphere, on the one hand, and for electrical and mechanical operating equipment, on the other hand.

Available types of ignition protection for electrical operating equipment in gas are, for example: intrinsic safety Ex i, flameproof enclosure Ex d, increased safety Ex e, and pressurized enclosures Ex p.

Connection elements or systems of this type that should also be operated in hazardous areas therefore have to satisfy very high safety demands with respect to explosion prevention and protection. It is here in particular a question of safely avoiding the formation of sparks or of at least ensuring that a spark that has been produced in the event of a defect does not have any effects on the environment. Corresponding standards in associated protective classes have been defined for this purpose. The explosion prevention and protection is achieved in the protective class having the title intrinsic safety (Ex i) in that the values for an electrical parameter (current, voltage, power) are respectively below a respectively predefined limit value at all times so that no ignition spark is generated even in the event of a defect. In the further protective class having the title increased safety (Ex e), the explosion prevention and protection is achieved in that the spatial distances between two different electrical potentials are so large that a spark generation cannot occur due to the distance even in the event of a defect. In the further protective class having the title flameproof enclosure (Ex d), the explosion prevention and protection is achieved in that a flameproof enclosure is formed. In the type of ignition protection of flameproof enclosure (Ex d), the function is based on the enclosure of any explosion that may occur in the housing interior. This is achieved by an explosion flameproof design of the housing together with flameproof joints at all housing openings. The surface temperature furthermore also has to be restricted on the occurrence of a defect to be expected below the ignition temperature of the surrounding explosive atmosphere. The demands on operating equipment of this type of ignition protection are described in the standard EN 60079-1. This type of ignition protection is also suitable when ignition sources occur in the interior of the operating equipment in non-disrupted operation.

Electrical signals are typically introduced into or removed from Ex d protected spaces via feedthroughs. This is done, on the one hand, by special cable screw connections or by conductor feedthroughs.

The feedthrough of these electrical signals into an Ex d protected space has to take place under standardized conditions in order not to allow a possible explosion in the Ex d space to escape to the outside. In this respect, ignition gaps must be observed to extinguish a flame front on its way to the outside and to use materials that also maintain the protective function of pressure and resistance to bursting after aging for years.

Conductor feedthroughs are classically used for this work. They comprise a sleeve, a specific variable number and type of conductors, and a socketing that is located between the conductors and the sleeve. The total system is flameproof. The disadvantages of a classical conductor feedthrough are a complex assembly of the cable ends on both sides and the long term wiring of the cables thereby required. A further disadvantage is a wiring that is prone to defects and the large space requirements of the cables. Conductor feedthroughs are expensive.

U.S. Pat. No. 9,534,939 B3 discloses a multipart printed circuit board feedthrough that can be disassembled into its starting components again. The disadvantages of the multipart printed circuit board feedthrough are that a large number of individual parts to be manufactured having great precision are required. The individual parts have to be shown to observe an ignition gap between one another. A complete dimensional check of all the parts is thereby necessary. High manufacturing costs thereby arise in total.

Devices are furthermore known in which a printed circuit board is fixedly cast in an Ex d housing. It is not replaceable and is a fixed component of the housing.

The disadvantage of the variant that is fixedly cast in the housing is that the components, in particular the printed circuit board, are not replaceable. A complete housing part has to be replaced on a defect of the printed circuit board. The solution is inflexible since it cannot be used in other housings and there is no variability with respect to the type and number of signals.

It is an object of the invention to provide an improved connection element.

The object is satisfied in accordance by a connection element for the electrical connection of a first electrical assembly and a second electrical assembly, wherein one of the assemblies is disposed in an explosion protected space and the connection element is arranged in an opening to the explosion protected space and closes the opening, wherein the connection element has a cylindrical sleeve, with the cylindrical sleeve being releasably arrangeable in a holder of the opening, the connection element having at least one printed circuit board in the sleeve, with the printed circuit board having a plurality of conductor tracks for the electrical connection of the first and second electrical assemblies, with the connection element having a cast part, with the printed circuit board being fixed and sealed in the sleeve by means of the cast part, and with respective ends of the printed circuit board having the respective conductor tracks projecting from the cast part.

The object is further satisfied by a system having a connection element for the electrical connection of a first electrical assembly and a second electrical assembly, wherein one of the assemblies is disposed in an explosion protected space and the connection element is arranged in an opening to the explosion protected space and closes the opening, wherein the connection element has a cylindrical sleeve, with the cylindrical sleeve being releasably arrangeable in a holder of the opening, the connection element having at least one printed circuit board in the sleeve, with the printed circuit board having a plurality of conductor tracks for the electrical connection of the first and second electrical assemblies, with the connection element having a cast part, with the printed circuit board being fixed and sealed in the sleeve by means of the cast part, and with respective ends of the printed circuit board having the respective conductor tracks projecting from the cast part.

The connection element or the printed circuit board feedthrough comprises the cylindrical sleeve, the cast part, and the at least one printed circuit board. The signals are conducted over the conductor tracks of the at least one printed circuit board.

The printed circuit board can also be called a printed wiring board. The designations printed circuit board and printed wiring board are used as synonymous terms.

A synergetic solution for sealing is achieved by the individual components of the connection element. The cast part having a molding compound ensures the bonded ignition gap over the total service life of the connection element.

In accordance with the invention, a considerable reduction of the assembly times of the connection element or of the printed circuit board feedthrough is achieved. A complete wiring time of approximately one hour is saved with respect to a conductor feedthrough having, for example, 40 individual conductors, for example. An avoidance of incorrect wiring is furthermore completely achieved.

The connection element is substantially more favorable than an existing conductor feedthrough since only a few individual components are required. The printed circuit board combines a plurality of conductor tracks that form a plurality of signal lines. For example, at least 20, at least 40, or at least 60 individual conductor tracks are provided on the printed circuit board. Intrinsic or non-intrinsic signals are conducted over the conductor tracks, for example. A variable transmission in the type and number of signals can be provided by the plurality of conductor tracks.

Precious construction space in front of and behind the printed circuit board feedthrough is considerably reduced in the cast part due to the provided printed circuit board and the relatively short projections over the cast part in comparison with conductors since no space has to be kept free for cables and for the assembly of the cables.

The printed circuit board is preferably made as a rigid printed circuit board. The printed circuit board can, however, also be formed as a flexible printed circuit board. The printed circuit board is, for example, formed as a flexboard or as a rigid flex circuit board. The printed circuit board has a thickness of approximately 1 mm to 3 mm, for example, in particular a thickness of 1.5 mm. The printed circuit board is made of FR-4, for example. FR-4 or also FR4 specifies a class of flame-resistant and flame-retardant composite materials, comprising epoxy resin and glass fiber fabric.

A single part license for the Ex d area can advantageously take place for the connection element. The licensed connection element can thus advantageously be used as a licensed component in other empty housings. The licensing effort for further devices is thereby considerably reduced.

In the standard format of the sleeve dimension, standard-Ex d-housing openings can be mounted both with a classical conductor feedthrough and with the connection element in accordance with the invention.

The first electrical assembly and the second electrical assembly can be a first electronic assembly and a second electronic assembly. The names electrical assembly and electronic assembly are to be considered equivalent here.

The cylindrical sleeve is made from aluminum, for example. However, different corrosion resistant meals can also be used to manufacture the cylindrical sleeve. The cylindrical sleeve can be formed from stainless steel, for example. The cylindrical sleeve can, however, also be manufactured from plastic.

The cast part is made from polyurethane, for example. Polyurethanes (abbreviated to PUR or sometimes also to PU) are plastics or synthetic resins that are produced from the polyaddition reaction of dialcohols (diols) or polyols with polyisocyanates. Depending on the degree of crosslinking and/or on the used isocyanate component or OH component, thermosetting plastics or thermoplastics are obtained that can be considered as materials for the cast part.

Further exemplary molding compounds on a polyurethane base that can be considered for the cast part are, for example:

PU vacuum cast resins: different products having a short pot life that e.g. correspond to mechanical and thermal specifications or optical aspects similar to mass produced materials (thermoplastic injection molding: ABS, PP, POM, PS, PC, PMMA etc.). They are processed in a vacuum casting plant.

PU fast cast resins: products that are relatively simply to process, that have a short pot life, and do not have to be processed in a vacuum.

Elastomer hardening PU cast resins: Products having different degrees of hardness located in the Shore A and Shore D ranges.

Electrical molding compounds: for casting around/sheathing electrical and electronic components (potting) for the purpose of electrical insulation and for the protection against aggressive environmental conditions (chemical, temperature, vibrations, mechanical).

Furthermore silicone or epoxy resin are, for example, suitable as the cast material for the cast part.

Silicone (also silicones; singular silicone), chemically more precisely poly (organo) siloxanes, is a designation for a group of synthetic polymers in which silicon atoms are linked via oxygen atoms. Silicones adopt an intermediate position between inorganic and organic links, in particular between silicates and organic polymers, due to their typically inorganic structure, on the one hand, and the organic residues, on the other hand. They are hybrids to a certain extent and have a unique property spectrum that is not achieved by any other plastic.

Epoxy resins or in brief EP resins are synthetic resins that carry epoxide groups. They are reaction resins that react with a hardener to form a thermosetting plastic after mixing. The hardener here is a reaction partner and together with the resin forms a macromolecular polyether with, as a rule, two terminal epoxide groups. Dyes and further additives can be integrated depending on the application. After the hardening, epoxy resins have good mechanical properties and good temperature and chemical resistance.

The connection element withstands a pressure up to approximately 30 bar, for example. However, connection element can also be manufactured that withstand a higher pressure.

In a further development of the invention, the ends of the printed circuit board are configured for a connector holder.

Exposed conductor contacts that are plugged into commercial plug connectors are located at the ends of the printed circuit board, for example. A plurality of conductor contacts or a plurality of signals are thus plugged simultaneously and protected against polarity reversal. Provision can, however, also be made that a respective plug connector that is connected by means of a matching counterpiece is arranged at or soldered to the ends of the printed circuit boards.

In a further development of the invention, the ends of the printed circuit board are configured for a cable connection. The ends of the printed circuit board are formed as solder contacts, for example.

Cables are soldered, either directly or using special crimp sleeves, to the ends of the printed circuit board, for example.

In a further development of the invention, the cylindrical sleeve or the connection element is plugged into the opening. A shape matched connection is provided, for example, between the margin of the opening and the connection element or cylindrical sleeve. For this purpose, the cylindrical sleeve, for example, has a shoulder or a collar, whereby a shape matched connection is provided between the margin of the opening and the connection element. The cylindrical sleeve can, however, also have a bayonet connector, whereby a shape match is likewise formed.

In a further development of the invention, the sleeve is screwed in the opening. A shape matched connection is likewise provided between the margin of the opening and the connection element or the cylindrical sleeve by a thread on the outer side of the cylindrical sleeve.

In a further development of the invention, the connection element has a plurality of printed circuit boards in the sleeve. The printed circuit board feedthrough receives a plurality of printed circuit boards to thus increase the number of contacts. The number of conductor tracks can thereby be increased. Stronger or wider conductor tracks can furthermore also be provided to provide power signals or energy supply lines. The distances of the conductor tracks can also be increased by a plurality of spaced apart printed circuit boards. In particular to avoid crossovers between the conductor tracks and to observe required protection distances.

In a further development of the invention, the printed circuit boards are spaced apart and arranged in parallel. A particularly space saving arrangement of the printed circuit boards is possible due to the parallel arrangement of the printed circuit boards. Adjacent printed circuit boards in particular each have smaller widths the further they are arranged outside the middle of the cylindrical sleeve.

In a further development of the invention, the sleeve has a pressure plate, with the pressure plate being arranged within the sleeve ad the pressure plate having at least one opening for the printed circuit board. The pressure plate is arranged in the cross-section of the cylindrical sleeve. The pressure plate in particular contacts an inner shoulder of the cylindrical sleeve so that the pressure plate is fixed in the cylindrical sleeve and can be supported at the cylindrical sleeve. The pressure plate can thereby withstand high environmental pressures.

The pressure plate is manufactured from plastic or from metal, for example. The pressure plate is manufactured from thermosetting plastic or a thermoplastic, for example.

The pressure plate is made from aluminum, for example. However, different corrosion resistant meals can also be used to manufacture the pressure plate. The pressure plate can be formed from stainless steel, for example.

In a further development of the invention, the pressure plate is arranged at an end of the sleeve and closes the sleeve in cross-section.

The pressure plate keeps the explosion pressure away from the molding compound and thus avoids the deformation of the cast part.

The manufacture takes place by plugging the printed circuit boards together in the pressure plate and in the cylindrical sleeve. The molding compound is then introduced at the open rear side and then hardens.

In a further development of the invention, the pressure plate has transverse surfaces, with the transverse surfaces being arranged transversely to the pressure plate and being connected to the pressure plate in one piece. The stability of the pressure plate is improved by the transverse surfaces or ribs. Due to the transverse surfaces, a torsional stiffness is improved and the deformation of the pressure plate on the application of pressure is improved. The transverse surfaces are arranged in parallel with and spaced apart from one another, for example. A lattice structure can, however, also be formed by the transverse surfaces.

In a further development of the invention, the printed circuit board has electronic circuits. In comparison with conductor feedthroughs, small electronic circuits can be integrated on the printed circuit board. Electronic circuits can in particular be arranged on the printed circuit board, for example for signal adaptation, for protection wiring, for signal interference suppression, and/or for signal preparation.

The invention will also be explained in the following with respect to further advantages and features with reference to the enclosed drawing and embodiments.

The Figures of the drawing show in:

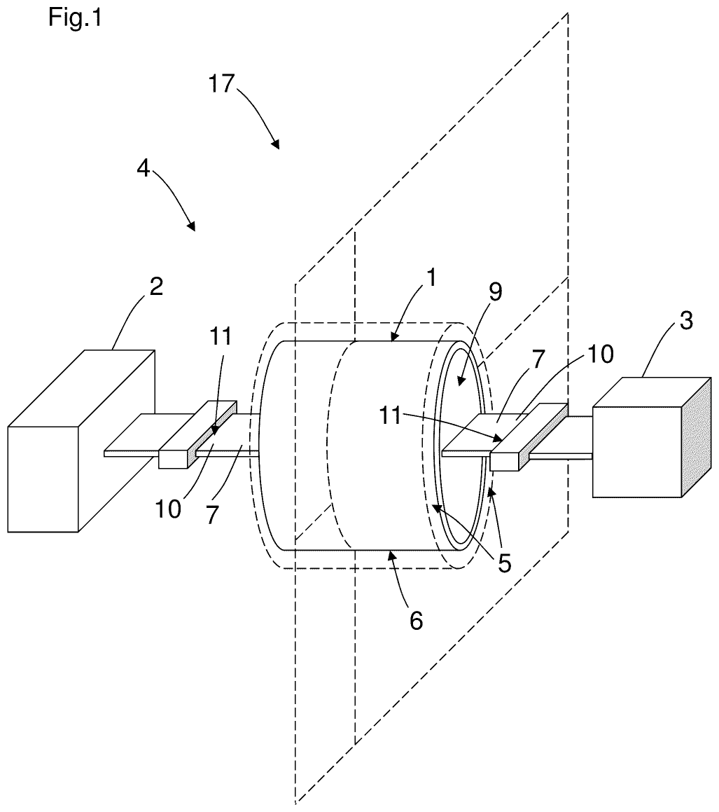

FIGS. 1 to 8 respectively a connection element.

In the following Figures, identical parts are provided with identical reference numerals.

FIG. 1 shows a system 17 having a connection element and a connection element for the electrical connection of a first electrical assembly 2 and a second electrical assembly 3, wherein one of the assemblies 2, 3 is disposed in an explosion protected space 4 and the connection element 1 is arranged in an opening to the explosion protected space 4 and closes the opening 5, wherein the connection element 1 has a cylindrical sleeve 6, with the cylindrical sleeve 6 being releasably arrangeable in a holder of the opening 5, the connection element 1 having at least one printed circuit board 7 in the cylindrical sleeve 6, with the printed circuit board 7 having a plurality of conductor tracks for the electrical connection of the first electrical assembly 2 and the second electrical assembly 3, with the connection element 1 having a cast part 9, with the printed circuit board 7 being fixed and sealed in the cylindrical sleeve 6 by means of the cast part 9, and with respective ends of the printed circuit board 7 having the respective conductor tracks projecting from the cast part 9. The ends of the printed circuit board 7 are formed for a plug holder 11, for example.

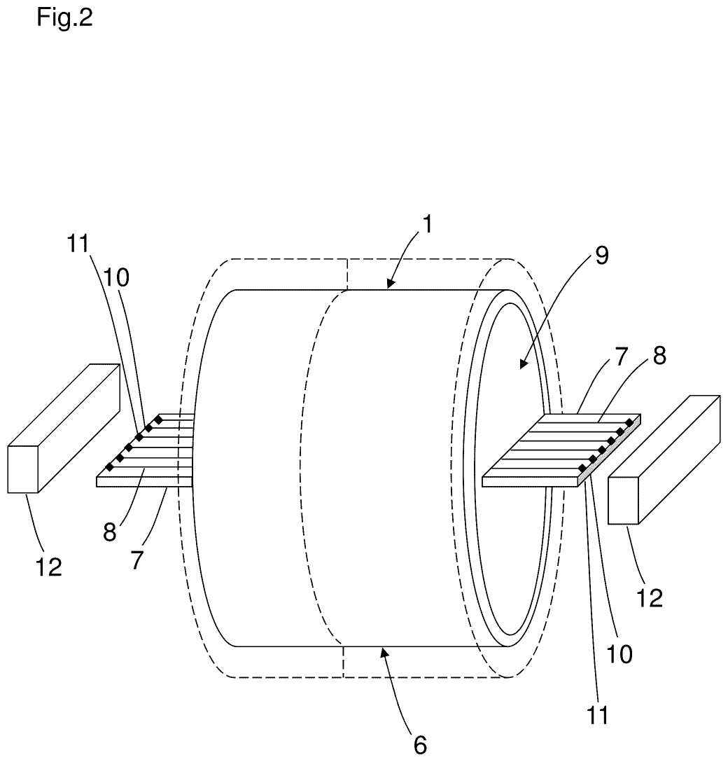

The connection element 1 is shown in more detail in FIG. 2. The connection element 1 or the printed circuit board feedthrough comprises at least the cylindrical sleeve 6, the cast part 9, and the at least one printed circuit board 7. The signals are conducted over the conductor tracks 8 of the at least one printed circuit board 7. Exposed conductor contacts that are plugged into commercial plug connectors 12 are located at the ends of the printed circuit board 7, for example. A plurality of conductor contacts or a plurality of signals are thus plugged simultaneously and protected against polarity reversal. Provision can, however, also be made that a respective plug connector 12 that is connected by means of a matching counterpiece is arranged at or soldered to the ends 10 of the printed circuit board 7.

The printed circuit board 7 combines a plurality of conductor tracks 8 that form a plurality of signal lines. For example, at least 20, at least 40, or at least 60 individual conductor tracks 8 are provided on the printed circuit board 7. Intrinsic or non-intrinsic signals are conducted over the conductor tracks 8, for example. A variable transmission in the type and number of signals is provided by the plurality of conductor tracks 8.

Precious construction space in front of and behind the printed circuit board feedthrough is considerably reduced in the cast part 9 due to the provided printed circuit board 7 and the relatively short projections over the cast part 9 in comparison with conductor lines since no space has to be kept free for cables.

The cylindrical sleeve 6 is made from aluminum, for example. The cylindrical sleeve 6 can be formed from stainless steel, for example. The cylindrical sleeve 6 can, however, also be manufactured from plastic. The cylindrical sleeve can, for example, be a circular cylindrical sleeve.

The cast part 9 is made from polyurethane, for example. Furthermore silicone or epoxy resin are, for example, suitable as the cast material for the cast part 9.

The connection element 1 withstands a pressure up to approximately 30 bar, for example. A connection element 1 can, however, also be manufactured that can withstand a higher pressure.

The outer contour of the cylindrical sleeve 6 forms the ignition gap.

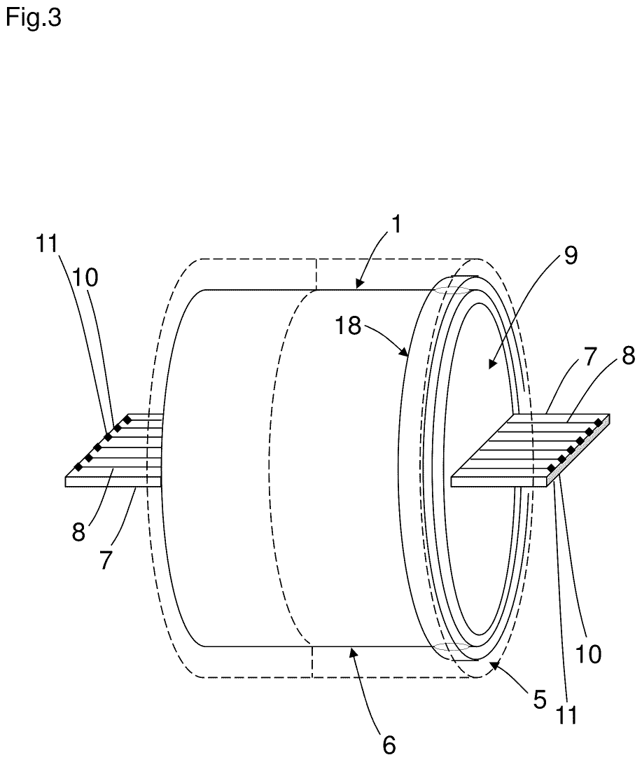

In accordance with FIG. 3, the cylindrical sleeve 6 or the connection element 1 is plugged into the opening 5. A shape matched connection is provided, for example, between the margin of the opening 5 and the connection element 1 or the cylindrical sleeve 6. For this purpose, the cylindrical sleeve 6, for example, has a shoulder 16 or a collar, whereby a shape matched connection is provided between the margin of the opening 5 and the connection element 1. The cylindrical sleeve 6 can, however, also have a bayonet connector, whereby a shape match is likewise formed.

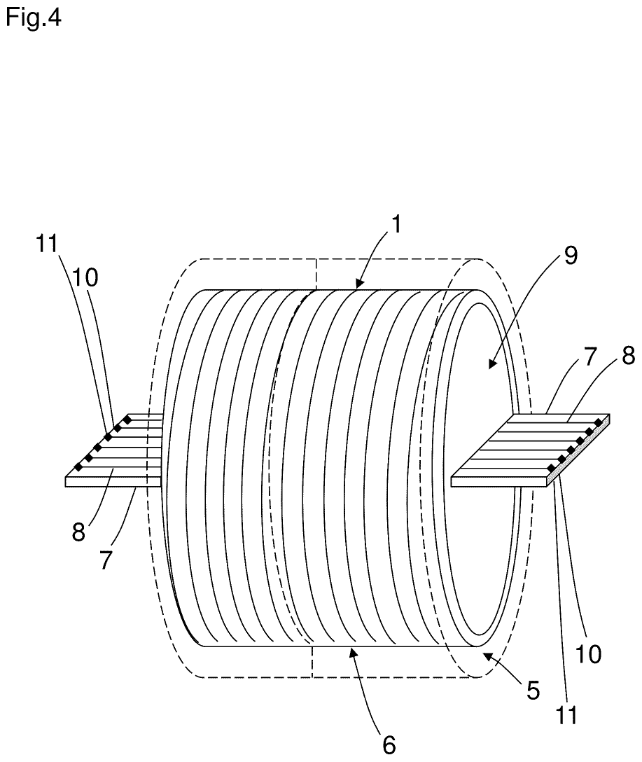

The cylindrical sleeve 6 in accordance with FIG. 4 is screwed in the opening 5, for example. A shape matched connection is likewise provided between the margin of the opening and the connection element 1 or the cylindrical sleeve 6 by a thread on the outer side of the cylindrical sleeve 6.

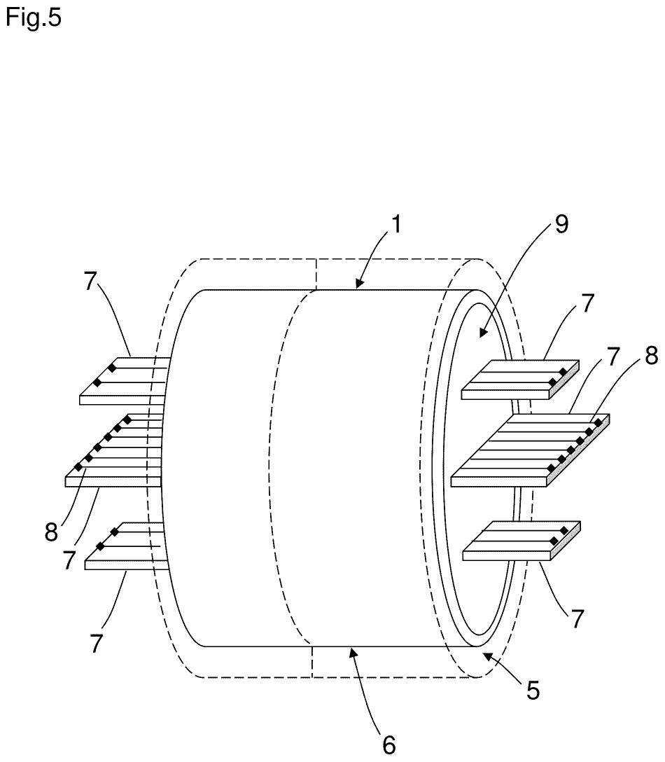

The connection element 1 in the cylindrical sleeve 6 in accordance with FIG. 5 has a plurality of printed circuit boards 7, for example. The printed circuit board feedthrough receives a plurality of printed circuit boards 7 to thus increase the number of contacts. The number of conductor tracks 8 can thereby be increased. Stronger or wider conductor tracks 8 can furthermore also be provided to provide power signals or energy supply lines. The distances of the conductor tracks 8 can also be increased by a plurality of spaced apart printed circuit boards 7. In particular to avoid crossovers between the conductor tracks 8 and to observe required protection distances.

The printed circuit boards 7 are arranged spaced apart and in parallel, for example. A particularly space saving arrangement of the printed circuit boards 7 is possible due to the parallel arrangement of the printed circuit boards 7. Adjacent printed circuit boards 7, for example, each have smaller widths the further they are arranged outside the middle of the cylindrical sleeve 6. This applies, for example, to the part of the printed circuit board in the feedthrough. The part of the printed circuit board having the plug end can then again be wider or also of the same width.

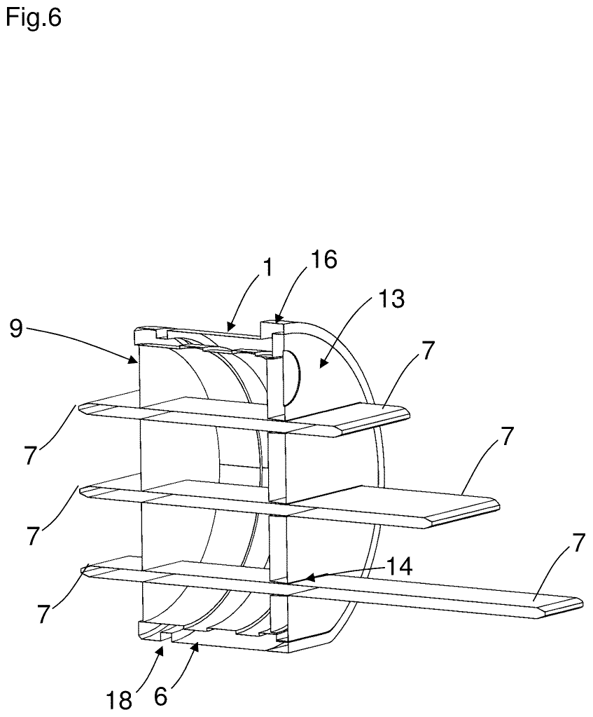

The connection element 1 is shown in a cross-sectional representation in accordance with FIG. 6. In accordance with FIG. 6, the cylindrical sleeve 6 has a pressure plate 13, with the pressure plate 12 being arranged within the cylindrical sleeve 6 and the pressure plate 13 having at least one opening 14 for the printed circuit board 7. The pressure plate 13 is arranged in the cross-section of the cylindrical sleeve 6. The pressure plate 13 in particular contacts an inner shoulder of the cylindrical sleeve so that the pressure plate 13 is fixed in the cylindrical sleeve 6 and can be supported at the cylindrical sleeve 6. The pressure plate 13 can thereby withstand high environmental pressures. The cylindrical sleeve 6 furthermore has a circumferential groove 18.

The pressure plate 13 is manufactured from plastic or from metal, for example. The pressure plate 13 is manufactured from thermosetting plastic or a thermoplastic, for example.

The pressure plate 13 is made from aluminum, for example. However, different corrosion resistant meals can also be used to manufacture the pressure plate 13. The pressure plate 13 can be formed from stainless steel, for example.

In accordance with FIG. 6, the pressure plate 13 is arranged at an end of the cylindrical sleeve 6 and closes the cylindrical sleeve 6 in the cross-section.

The pressure plate 13 keeps the explosion pressure away from the cast part 9 or from the molding compound and thus avoids the deformation of the cast part 9.

The manufacture takes place, for example, by plugging the printed circuit boards 7 together in the pressure plate 13 and in the cylindrical sleeve 6. The molding compound is then introduced at the open rear side, for example, and then hardens to form the cast part 9.

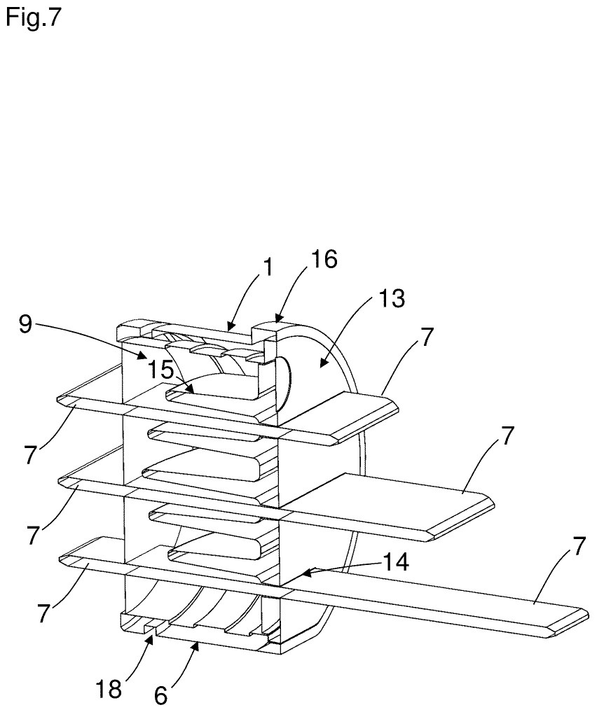

In accordance with FIG. 7, the pressure plate 13 has transverse surfaces 15, with the transverse surfaces 15 being arranged transversely to the pressure plate 13 and being connected to the pressure plate 13 in one piece. The stability of the pressure plate 13 is improved by the transverse surfaces 15 or ribs. Due to the transverse surfaces 15, a torsional stiffness is improved and the deformation of the pressure plate 13 on the application of pressure is improved. The transverse surfaces 15 are arranged in parallel with and spaced apart from one another, for example. A lattice structure can, however, also be formed by the transverse surfaces 15. In this respect, individual transverse surfaces 15 are arranged transversely to one another and transversely to the pressure plate 13.

The printed circuit board 7 has electronic circuits, for example. In comparison with conductor feedthroughs, small electronic circuits can be integrated on the printed circuit board 7. Electronic circuits can in particular be arranged on the printed circuit board 7, for example for signal adaptation, for protection wiring, for signal interference suppression, and/or for signal preparation.

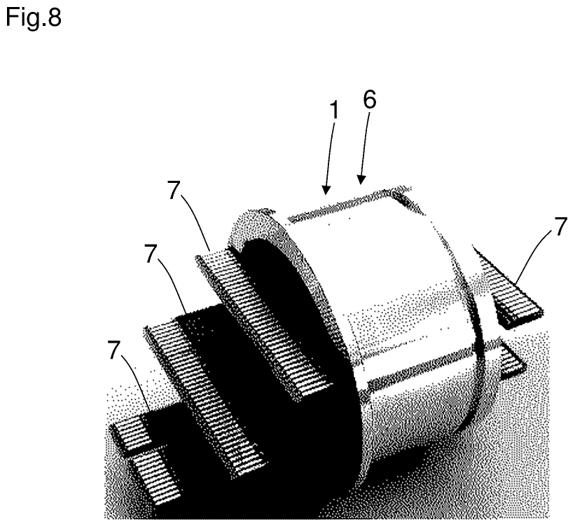

The connection element 1 in accordance with FIG. 8 in the cylindrical sleeve 6 has a plurality of printed circuit boards 7, for example. The printed circuit boards 7 are arranged spaced apart and in parallel, for example. Adjacent printed circuit boards 7, for example, each have smaller widths the further they are arranged outside the middle of the cylindrical sleeve 6. This applies, for example, to the part of the printed circuit board in the feedthrough. The part of the printed circuit board having the plug end can then again be wider or also of the same width. The signals are conducted over the conductor tracks of the at least one printed circuit board 7. Exposed conductor contacts that are plugged into commercial plug connectors 12 are located at the ends of the printed circuit boards 7, for example.

### REFERENCE NUMERALS

1 connection element
2 first electrical assembly
3 second electrical assembly
4 explosion protected space
5 opening
6 cylindrical sleeve
7 circuit board
8 conductor tracks
9 cast part
10 ends of the printed circuit board
11 plug holder
12 plug
13 pressure plate
14 opening for printed circuit board
15 transverse surfaces of the pressure plate
16 shoulder
17 system
18 groove

1. A connection element for the electrical connection of a first electrical assembly and a second electrical assembly, wherein one of the first and second assemblies is disposed in an explosion protected space and the connection element is arranged in an opening to the explosion protected space and closes the opening,
wherein the connection element has a cylindrical sleeve, with the cylindrical sleeve being releasably arrangeable in a holder of the opening;
the connection element having at least one printed circuit board in the cylindrical sleeve, with the printed circuit board having a plurality of conductor tracks for the electrical connection of the first electrical assembly and the second electrical assembly;
with the transmission element having a cast part;
with the printed circuit board being fixed and sealed in the sleeve by means of the cast part; and
with respective ends of the printed circuit board having the respective conductor tracks projecting from the cast part.

2. The connection element in accordance with claim 1, wherein the ends of the printed circuit board are configured for a plug holder.

3. The connection element in accordance with claim 1, wherein the ends of the circuit board are formed for a cable connection.

4. The connection element in accordance with claim 1, wherein the cylindrical sleeve is plugged in the opening.

5. The connection element in accordance with claim 1, wherein the cylindrical sleeve is screwed in the opening.

6. The connection element in accordance with claim 1, wherein the connection element has a plurality of circuit boards in the cylindrical sleeve.

7. The connection element in accordance with claim 2, wherein the circuit boards are arranged spaced apart and in parallel.

8. The connection element in accordance with claim 1, wherein the cylindrical sleeve has a pressure plate, with the pressure plate being arranged within the cylindrical sleeve and the pressure plate having at least one opening for the printed circuit board.

9. The connection element in accordance with claim 1, wherein the pressure plate is arranged at an end of the cylindrical sleeve and closes the cylindrical sleeve in the cross-section.

10. The connection element in accordance with claim 1, wherein the pressure plate has transverse surfaces with the transverse surfaces being arranged transversely to the pressure plate and being connected to the pressure plate in one piece.

11. The connection element in accordance with claim 1, wherein the printed circuit board has electronic circuits.

12. A system having a connection element for the electrical connection of a first electrical assembly and a second electrical assembly, wherein one of the first and second assemblies is disposed in an explosion protected space and the connection element is arranged in an opening to the explosion protected space and closes the opening,
wherein the connection element has a cylindrical sleeve, with the cylindrical sleeve being releasably arrangeable in a holder of the opening;
the connection element having at least one printed circuit board in the cylindrical sleeve, with the printed circuit board having a plurality of conductor tracks for the electrical connection of the first electrical assembly and the of the second electrical assembly;
with the connection element having a cast part
with the printed circuit board being fixed and sealed in the cylindrical sleeve by means of the cast part; and
with respective ends of the printed circuit board having the respective conductor tracks projecting from the cast part.
